(19) United States
(12) Patent Application Publication
(10) Pub. No.: US 2024/0038636 A1
(43) Pub. Date: Feb. 1, 2024

(54) METHOD OF MANUFACTURING SEMICONDUCTOR DEVICES, CORRESPONDING SUBSTRATE AND SEMICONDUCTOR DEVICE

(71) Applicant: STMicroelectronics S.r.l., Agrate Brianza (MB) (IT)

(72) Inventor: Dario VITELLO, Merate (LC) (IT)

(73) Assignee: STMicroelectronics S.r.l., Agrate Brianza (MB) (IT)

(21) Appl. No.: 18/224,701

(22) Filed: Jul. 21, 2023

(30) Foreign Application Priority Data
Jul. 28, 2022 (IT) 102022000016008

(51) Int. Cl. H01L 23/495; H01L 23/31; H01L 21/56

(52) U.S. Cl. CPC H01L 23/49541; H01L 23/49503; H01L 23/3107; H01L 21/561

(57) ABSTRACT

A semiconductor die mounting substrate, such as a pre-molded leadframe, is provided with die pads, wherein each die pad has opposed first and second surfaces as well as tie bars projecting therefrom. Semiconductor dice are mounted at the first surface of the die pads. A molding encapsulation material surrounds the semiconductor dice mounted at the first surface of the die pads to produce semiconductor devices, with the semiconductor devices being mutually coupled via the tie bars. The tie bars are then cut transverse to their longitudinal direction at an intermediate singulation location to singulate the semiconductor devices into individual semiconductor devices. The tie bars have a hollowed-out portion with a channel-shaped cross-sectional profile at the intermediate singulation location. Easier-to-cut tie bars can be provided without impairing their stiffness in comparison with tie bars having full rectangular/square cross-sectional shapes.

### PRIORITY CLAIM

This application claims the priority benefit of Italian Application for Patent No. 102022000016008 filed on Jul. 28, 2022, the content of which is hereby incorporated by reference in its entirety to the maximum extent allowable by law.

### TECHNICAL FIELD

The description relates to manufacturing semiconductor devices.

Solutions as described herein can be applied to packaging integrated circuits (ICs), for instance in packages including a leadframe with an exposed pad.

### BACKGROUND

In current manufacturing processes of semiconductor devices, plural devices manufactured concurrently in a chain or strip are then separated into single individual devices in a final “singulation” step.

Package singulation is the last step of the assembly process: once a protective encapsulation is molded to complete the package, each individual package is separated from the rest of chain or strip.

This involves mechanically cutting (e.g., via a blade) tie bars included in a leadframe ribbon common to the devices in the chain or strip. Mechanical cutting induces stresses that may lie at the basis of leadframe/mold (encapsulation) detachment. This is an undesired effect that may in turn cause premature failure during reliability tests or during the operating life of the device.

Conventional leadframes comprise uniform, e.g., rectangular tie bars with constant thickness. This is the thickness (e.g., 0.2 mm) of the copper ribbon from which the leadframe is manufactured.

Using thinner tie bars may facilitate cutting during singulation, reducing stresses that may lie at the basis of leadframe/mold (encapsulation) detachment. Using thinner tie bars however increases the risk of die pad tilt during the assembly process.

There is a need in the art to address the issues discussed in the foregoing.

### SUMMARY

One or more embodiments relate to a method.

One or more embodiments also relate to a corresponding substrate (e.g., a leadframe strip or ribbon for use in manufacturing semiconductor devices).

One or more embodiments also relate to a corresponding semiconductor device.

The solutions presented herein comprise a substrate such as a leadframe in which tie bars have a channel-shaped (U-shaped) cross-section at least at their median part that is cut during singulation after molding.

Such a channel or (inverted) U shape can be bestowed on the tie bars done during leadframe manufacturing using a coining or etching process, for instance.

A higher stiffness (a higher moment of inertia) of the tie bars can thus be achieved in comparison with tie bars of constant cross section. This provides improved support of the die pads avoiding tilt/bending. At the same time, channel-shaped or U-shaped tie bars will be easier to be cut during singulation.

In solutions presented herein, coining or etching a recess in leadframe tie bars facilitates providing a channel-shape or U-shape section in the median portion of these tie bars. After mounting semiconductor chips or dice on the die pads in the leadframe and molding an encapsulation thereon, singulation of the individual package units from the leadframe may take place cutting through the channel-shaped (U-shaped) median portion of the tie bars.

Visual inspection of resulting package flanks will reveal the presence of such a channel shape or U-shape in the remainder of the tie bars remaining exposed at the package flanks.

### BRIEF DESCRIPTION OF THE DRAWINGS

One or more embodiments will now be described, by way of example only, with reference to the annexed figures, wherein:

FIG. 1 is a plan view from the front or top side of a semiconductor device in the process of being manufactured,

FIG. 2 is a plan view from the back or bottom side of the semiconductor device of FIG. 1;

FIG. 3 is a plan view from the back or bottom side of the semiconductor device of FIG. 1 and FIG. 2 illustrated in a later stage of the assembly process;

FIG. 4 is a view of the portion of FIG. 1 indicated by the arrow IV reproduced on an enlarged scale and with various elements removed for clarity;

FIG. 5 is a comparative diagram of characteristics of conventional tie bars and tie bars as described herein; and

FIG. 6 is a side view of a semiconductor device as described herein.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description like parts or elements are indicated in the various figures with like reference signs, and a corresponding description will not be repeated for each and every figure.

Semiconductor devices as considered herein comprise a substrate (leadframe) 12 comprising one or more die pads 12A having one or more semiconductor chips or dice 14 arranged thereon plus an array of electrically conductive leads 12B.

As used herein, “chip/s” and “die/dice” will be regarded as synonyms. For simplicity, a single die pad 12A is illustrated having a single integrated circuit semiconductor chip or dice 14 mounted thereon.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, e.g., 12B) that from an outline location extend inwardly in the direction of a semiconductor chip or die (e.g., 14) thus forming an array of electrically-conductive formations from a die pad (e.g., 12A) configured to have at least one semiconductor chip or die 14 attached thereon. This may be via conventional means such as a die attach adhesive (a die attach film or DAF, for instance).

A leadframe 12 as illustrated herein can be of the pre-molded type, that is a type of leadframe comprising a sculptured metal (e.g., copper) structure comprising die pads 12A and leads 12B formed by etching a metal sheet and including empty spaces that are filled by a resin 12C “pre-molded” on the sculptured metal structure.

Semiconductor devices as considered herein comprise electrically conductive formations (e.g., wires in a wire bonding pattern) coupling the semiconductor chip(s) 14 to leads 12B (outer pads) in the substrate 12 as well.

Such a wire bonding pattern is not visible in the figures for simplicity.

An insulating encapsulation (e.g., a resin) 16 is molded on the assembly thus formed to complete the plastic body of the device.

As an (at least partial) alternative to a wire bonding pattern as discussed previously, solutions as described herein may include electrically conductive formations provided via laser direct structuring (LDS) of an encapsulation of LDS material as taught, for example, by: United States Patent Publication Nos. 2018/0342453 A1, 2019/0115287 A1, 2020/0203264 A1, 2020/0321274 A1, 2021/0050226 A1, 2021/0050299 A1, 2021/0183748 A1, or 2021/0305203 A1 (all of which are incorporated herein by reference) which are exemplary of the use of LDS technology.

As illustrated in the side view of FIG. 6, devices 10 as considered herein are intended to be mounted on a substrate S such as a printed circuit board (PCB) using solder material for instance (not visible in the figures),

A device structure as discussed so far is conventional in the art, which makes it unnecessary to provide a more detailed description herein.

The present description relates to a manufacturing process of semiconductor devices wherein plural devices are manufactured concurrently to be finally separated into individual devices in a singulation step.

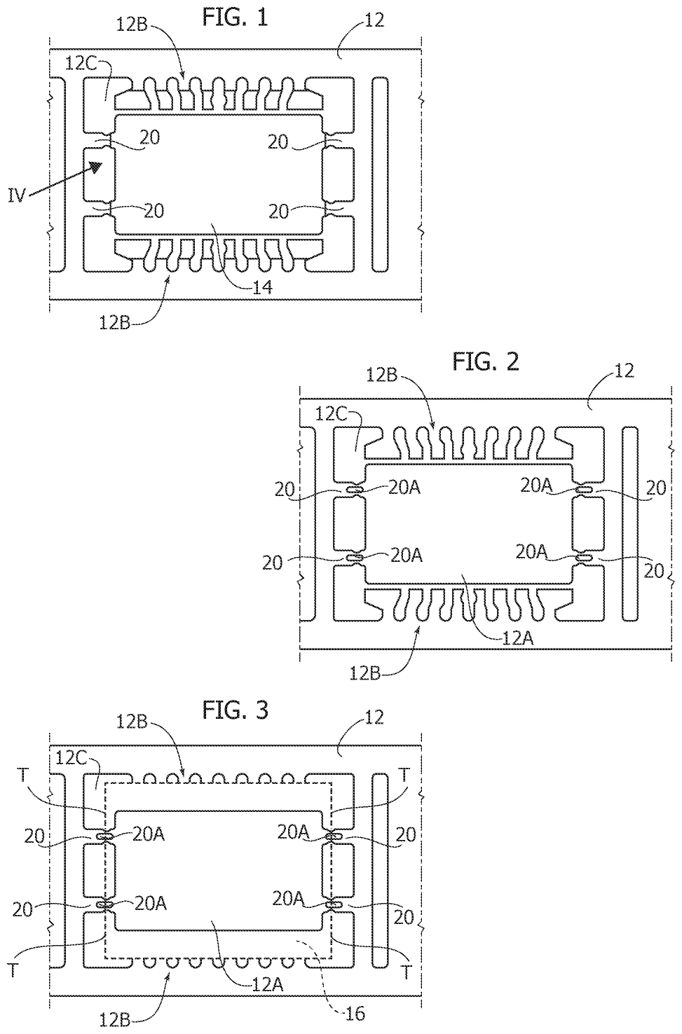

To that effect a chain or strip of devices are manufactured concurrently using, e.g., a strip-like leadframe 12 (a section of such a leadframe is visible in FIGS. 1 to 3) arranging the dice or chips 14 onto respective die pads 12A. These die pads are coupled to the strip structure via so-called tie bars 20.

Once the plastic body of the devices is completed by molding the insulating encapsulation 16 (see FIG. 3), individual devices 10 are separated from the chain or strip in a singulation step where the tie bars 20 are severed (e.g., cut via a rotary blade) at cutting lines/planes T.

Singulation as discussed so far is likewise conventional in the art, which makes it unnecessary to provide a more detailed description herein.

To summarize, such an assembly process comprises providing a semiconductor die mounting substrate (a planar leadframe 12, for instance) comprising a plurality of die pads 12A having opposed first and second surfaces as well as tie bars 20 projecting (radially) from the die pads 12A (in the plane of the substrate 12). The tie bars have a longitudinal direction (X20).

Semiconductor dice 14 are mounted at the first surface of the die pads 12A and encapsulation material 16 is molded onto the semiconductor dice 14 mounted at the first surface of the die pads 12A, so that a plurality of semiconductor devices 10 that are mutually coupled via the tie bars 20 projecting from the die pads 12A.

As discussed, the encapsulation material 16 can be: an insulating resin (e.g., an epoxy resin) molded onto the semiconductor dice 14 mounted at the first surface of the die pads 12A and incorporating (embedding) wire bonding patterns of wires electrically coupling each die 14 with leads in a respective array of leads 12B of the leadframe 12; or a laser-activatable material to which laser machining (e.g., laser direct structuring, LDS) and (electroless/electrolytic) metal growth can be applied to provide electrically conductive formations (vias/traces) electrically coupling each die 14 with leads in a respective array of leads 12B of the leadframe 12 (see the United States Patent Publication documents mentioned in the foregoing).

The bars 20 are finally cut transverse to their longitudinal direction X20 at an intermediate singulation location. The semiconductor devices 10 are thus singulated into individual semiconductor devices.

As illustrated, the semiconductor die mounting substrate 12 is a ribbon substrate comprising a plurality of die pads 12A distributed along the length of the ribbon substrate 12 with the tie bars 20 projecting therefrom with their longitudinal direction X20 extending lengthwise of the ribbon substrate.

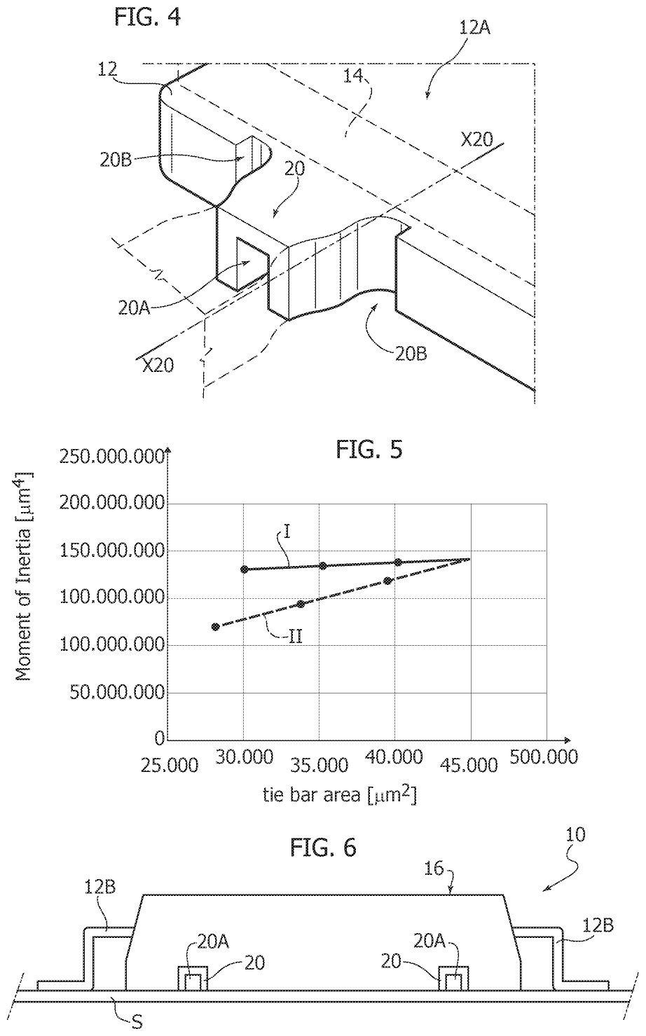

As visible in FIG. 4, for example in the plane parallel to the top and bottom surfaces of the leadframe, the tie bars 20 may have an hourglass shape with a narrowed waist portion and cutting takes place along cutting lines T halfway the waist portion.

As discussed, stress induced by the mechanical cut can induce detachment of the leadframe 12 from the encapsulation 16; this may undesirably cause premature failure during reliability tests or the operating life of the device 10.

Conventional leadframes 12 comprises uniform, e.g., rectangular tie bars 20 with a constant thickness: this is the thickness (e.g., 0.2 mm) of the metal ribbon — usually a copper ribbon—from which the leadframe 12 is manufactured.

Decreasing the (uniform) thickness of rectangular tie bars facilitates cutting at lines T to the detriment of the stability of the die pads 12A.

In solutions as discussed herein these issues are addressed by bestowing on the tie bars 20 a channel-shaped (U-shaped) cross-section, for example in the plane perpendicular to the top and bottom surfaces of the leadframe, at least at their median part (such as at the narrowed waist portion) that is expected to be cut during singulation after molding.

That is, in solutions as discussed herein the tie bars 20 have a hollowed-out portion 20A at the intermediate singulation location. The tie bars 20 thus have at the intermediate singulation location a channel-shaped cross-sectional profile.

FIG. 4 (this is a view of the portion of FIG. 1 indicated by the arrow IV reproduced on an enlarged scale, where various elements such as the pre-mold resin 12C are removed for clarity) shows that the tie bars 20 of the examples presented herein still have an “envelope” thickness equal to the thickness (e.g., 0.2 mm) of the metal ribbon from which the leadframe 12 is manufactured.

The tie bars 20 of the examples presented herein have at their intermediate section a hollowed-out channel shape (a U-shape is exemplary of such a channel shape) due to the presence of a cavity 20A.

The cavity 20A can result from a coining or etching process, for instance, during leadframe manufacturing.

Advantageously, the cavities 20A do not extend over the whole length of the tie bars 20 (in the longitudinal direction X20), but just at the intermediate section of the tie bars 20, e.g., at the location where cutting is expected to take place during singulation (see the planes T in FIG. 3).

During singulation, the tie bars 20 are cut (at the planes T of FIG. 3) essentially halfway their length.

In the enlarged view of FIG. 4 one half of a tie bar 20 which may result from such cutting is shown in full line, while the other half is shown in dashed lines; these two halves are separated from each other during the singulation step.

The enlarged view of FIG. 4 highlights the overall (lengthwise) hourglass shape of the tie bars 20 illustrated therein, with the cavity 20A advantageously extending (only) at the intermediate narrowed waist portion of the hourglass-shaped tie bars 20.

The enlarged view of FIG. 4 also illustrates a cavity 20A such that the channel shape thereof opens out at the back or bottom side of the leadframe 12 (opposite the front or top surface where the dice 14 are mounted).

That is, the tie bars 20 have a hollowed-out portion 20A at the intermediate singulation location, with the channel-shaped cross-sectional profile opening at the (second) surface of the die pads 12A opposite the (first) surface where the dice 14 are mounted.

While advantageous, this arrangement is not mandatory, insofar as the cavity 20A can be such that the channel shape opens out at the front or top side of the leadframe 12, where the dice 14 are mounted.

The enlarged view of FIG. 4 also illustrates the channel-shaped tie bars 20 projecting from the body of the leadframe 12 from a recessed portion thereof, that is with two channels (notches) 20B on both sides of the tie bar 20 and extending transverse to the plane of the leadframe 12, sidewise of the tie bars 20.

Hollowed out (channel-shaped, e.g., U-shaped) tie bars 20 as illustrated in FIG. 4 were found to provide a higher stiffness (a higher moment of inertia) in comparison with tie bars of a same cross-sectional area having constant (full) cross-section, thus providing improved support of the die pads avoiding tilt/bending.

FIG. 5 is a comparative diagram of characteristics (moment of inertia—microns⁴ vs. tie bar cross-sectional area—microns) of: hollowed out (channel-shaped or U-shaped) tie bars as described herein (curve labeled I), and conventional tie bars of constant (full) cross section (curve labeled II).

The diagram of FIG. 5 demonstrates that providing a recess or cavity 20A in the median portion of the tie bars 20 results in: a higher moment of inertia for a same cross-sectional area (of the median portion to be cut during singulation) and, consistently, a same moment of inertia for a smaller cross-sectional area (of the median portion to be cut during singulation).

A smaller cross-sectional area translates into lower cutting forces (and thus lower stress) involved in singulation while an adequate flexural stiffness can be retained in order to support the associated die pad 12A avoiding tilt/bending.

Solutions as described herein facilitate achieving a two-fold advantage, namely: pursuing a higher moment of inertia, and thus a higher stiffness and improved support for the die pads, countering tilting/bending, and reducing the cross-sectional area, with cutting at singulation made easier with reduced singulation stresses.

FIG. 6 shows that the channel shape or U-shape of the tie bars 20 will be revealed by the remainders of the tie bars being exposed at the flanks of the package of the device 10 after singulation (this may be a package including a leadframe with an exposed pad).

Two tie bars 20 at both (transversal) sides of the die pads 12A are illustrated in the figures.

Two pairs of tie bars arranged symmetrically at opposed sides of the die pads (that is, four tie bars 20 for each die pad 12A) are of course merely exemplary and non-limiting. Other arrangements such as, e.g., one tie bar and two bars arranged asymmetrically at opposed sides of the die pads (that is, three tie bars 20 for each die pad 12A) are of course possible.

Tie bars 20 as discussed herein thus facilitate having thinner (easier-to-cut) tie bars while avoiding any increased risk of die pad tilt in so far as a channel-shaped or U-shaped cross section bestows on the tie bars 20 a higher moment of inertia in comparison with a rectangular/square cross-sectional shape.

At the same time, coined/etched-out tie bars 20 will reduce the force/stress involved in separating an individual package 10 from the chain/strip during the final steps of the assembly process.

Without prejudice to the underlying principles, the details and embodiments may vary, even significantly, with respect to what has been described by way of example only without departing from the extent of protection.

The claims are an integral part of the technical teaching provided herein in respect of the embodiments.

The extent of protection is determined by the annexed claims.

1. A method, comprising:
mounting a semiconductor die at a first surface of each die pad of a plurality of die pads in a semiconductor die mounting substrate, each die pad having a second surface opposed to the first surface and further having tie bars projecting therefrom;
molding encapsulation material onto each semiconductor die mounted at the first surface of each die pad of the plurality of die pads to form a plurality of semiconductor devices which are coupled via said tie bars projecting from the die pads;
cutting each tie bar at an intermediate singulation location to singulate the plurality of semiconductor devices into individual semiconductor devices; and
wherein each tie bar has a hollowed-out portion at said intermediate singulation location, said hollowed-out portion defining a channel-shaped cross-sectional profile at said intermediate singulation location.

2. The method of claim 1, wherein said hollowed-out portion is provided in a surface of each tie bar which extends from the second surface of die pad.

3. The method of claim 1, wherein each tie bar has a length in a longitudinal direction extending away from the die pad, and wherein said hollowed-out portion extends over a part of said length in said longitudinal direction.

4. The method of claim 3, wherein each tie bar has an hourglass shape in said longitudinal direction with an intermediate narrowed waist portion and wherein said hollowed-out portion is provided at said intermediate narrowed waist portion.

5. The method of claim 1, wherein each tie bar projects from a recessed portion of the die pad with lateral grooves located sidewise of the tie bar.

6. The method of claim 1, wherein the semiconductor die mounting substrate is a ribbon substrate comprising said plurality of die pads distributed along a length of the ribbon substrate with each tie bar projecting from the die pad in a direction of said length of the ribbon substrate.

7. The method of claim, further comprising performing a coining operation to produce said hollowed-out portion at said intermediate singulation location.

8. The method of claim, further comprising performing an etching operation to produce said hollowed-out portion at said intermediate singulation location.

9. A semiconductor die mounting substrate, comprising:
a plurality of die pads having a first surface a second surface opposed to the first surface and further having tie bars projecting from each die pad;
wherein each tie bar has an intermediate singulation location; and
wherein each tie bar has a hollowed-out portion at each intermediate singulation location, said hollowed-out portion defining a channel-shaped cross-sectional profile at said intermediate singulation location.

10. The substrate of claim 9, wherein said hollowed-out portion is provided in a surface of each tie bar which extends from the second surface of die pad.

11. The substrate of claim 9, wherein each tie bar has a length in a longitudinal direction extending away from the die pad, and wherein said hollowed-out portion extends over a part of said length in said longitudinal direction.

12. The substrate of claim 11, wherein each tie bar has an hourglass shape in said longitudinal direction with an intermediate narrowed waist portion and wherein said hollowed-out portion is provided at said intermediate narrowed waist portion.

13. The substrate of claim 9, wherein each tie bar projects from a recessed portion of the die pad with lateral grooves located sidewise of the tie bar.

14. The substrate of claim 9, wherein the semiconductor die mounting substrate is a ribbon substrate comprising said plurality of die pads distributed along a length of the ribbon substrate with each tie bar projecting from the die pad in a direction of said length of the ribbon substrate.

15. A device, comprising:
a semiconductor die mounting substrate comprising a die pad having a first surface and a second surface opposed to the first surface and further including residuals of tie bars projecting from the die pad towards a distal singulation location;
a semiconductor die mounted at the first surface of the die pad; and
encapsulation material molded onto the semiconductor die mounted at the first surface of the die pad;
wherein the residuals of tie bars each have a hollowed-out portion at said distal singulation location;
wherein the residuals of tie bars each have at said distal singulation location a channel-shaped cross-sectional profile.

16. The device of claim 15, wherein said hollowed-out portion is provided in a surface of each tie bar which extends from the second surface of die pad.

17. The device of claim 15, wherein each tie bar has a length in a longitudinal direction extending away from the die pad, and wherein said hollowed-out portion extends over a part of said length in said longitudinal direction.

18. The substrate of claim 15, wherein each tie bar projects from a recessed portion of the die pad with lateral grooves located sidewise of the tie bar.

19. A method, comprising:
providing a leadframe including a plurality of die pads, each die pad having a first surface opposed to a second first surface and further having tie bars projecting from the die pad;
wherein providing the leadframe comprises providing at each tie bar a hollowed-out portion at an intermediate singulation location between die pads, said hollowed-out portion defining a channel-shaped cross-sectional profile at said intermediate singulation location;
mounting a semiconductor die to the first surface of each die pad;
encapsulating the leadframe and semiconductor dies in an encapsulation material; and
singulating by cutting through the encapsulation material and the tie bars at the intermediate singulation locations.

20. The method of claim 19, wherein providing the leadframe further comprises providing each tie bar with an hourglass shape in a longitudinal direction of the tie bar at the intermediate singulation location, said hourglass shape comprising an intermediate narrowed waist portion located at said hollowed-out portion.
